(19) United States
(12) Patent Application Publication
(10) Pub. No.: US 2016/0023891 A1
(43) Pub. Date: Jan. 28, 2016

(54) Component including a MEMS element and a cap structure including a media connection port

(71) Applicant: Robert Bosch GmbH, Stuttgart (DE)

(72) Inventor: Jochen REINMUTH, Reutlingen (DE)

(21) Appl. No.: 14/805,180

(22) Filed: Jul. 21, 2015

(30) Foreign Application Priority Data
Jul. 24, 2014 (DE) 10 2014 214 532.5

(51) Int. Cl. B81B 7/00; B81C 1/00

(52) U.S. Cl. CPC B81B 7/0041; B81C 1/00293; B81B 2203/0127; B81B 2203/0315; B81C 1/00158; B81B 2201/0264; B81B 2201/0257

(57) ABSTRACT

A structural concept for components includes a MEMS element, the micromechanical function of which requires a media connection to the surroundings, and including a cap structure for this micromechanical component, which may be implemented in a simple and cost-effective manner and which may be used to protect the micromechanical structure of MEMS elements very effectively against particles and interfering environmental influences despite media access. The cap structure closes at least one first cavity section above the micromechanical component and at least one second cavity section on the side of this micromechanical component, so that the two cavity sections are connected to one another, the connection area between the two cavity sections being configured as particle filters. The media connection port is situated in the area of the second cavity section.

### RELATED APPLICATION INFORMATION

The present application claims priority to and the benefit of German patent application no. 10 2014 214 532.5, which was filed in Germany on Jul. 24, 2014, the disclosure of which is incorporated herein by reference.

### FIELD OF THE INVENTION

The present invention relates generally to a component including a MEMS element, in whose layered structure at least one micromechanical component is implemented, the function of which requires a media connection to the surroundings, and including a cap structure for this micromechanical component, the media connection being implemented in the form of at least one port in the cap structure.

### BACKGROUND INFORMATION

Primary applications for the component concept under discussion here are components having a connection port for applying pressure to the diaphragm of a micromechanical pressure sensor component or a microphone component. In addition to the pressure sensor components or the microphone component, such components frequently also include additional MEMS elements and/or ASIC elements, the functions of which complement one another. The elements of the component are combined in a shared housing or package.

A structure variant for pressure sensor and microphone components provides that the MEMS element is mounted together with the additional elements of the component on a shared support and subsequently encapsulated using a molding compound. In this process, the pressure-sensitive diaphragm is usually kept clear using a stamp of the molding tool in order to create a pressure connection port in the mold housing. Thus, the media connection port is in this case formed directly above the diaphragm, so that the diaphragm is freely accessible from the outside and is comparatively unprotected. Moreover, different thermal expansion coefficients of the MEMS material and the molding compound have a disadvantageous impact on the sensor or microphone function in this structure variant.

In a particularly space-saving structure variant, the MEMS element is provided with a cap structure on the chip level. In this case, the media connection is generally made via a port in the cap structure, which is also formed above the diaphragm area. Such a cap structure may be implemented either in the layered structure of the MEMS element or in the form of a cap wafer, which is mounted on the MEMS element, so that the MEMS element and cap wafer form a chip stack.

The positioning of the media connection port directly above the micromechanical structure of the MEMS element proves to be problematic in several respects.

As already mentioned, the protective effect of a housing or a cap structure is considerably limited by a media connection port directly above the micromechanical structure of the MEMS element, since dirt particles and moisture are able to penetrate substantially unhindered the micromechanical structure of the MEMS element via the media connection port. This may result in a considerable impairment of the MEMS function.

However, the manufacture of such a media access port is also problematic. It must thus be ensured that the MEMS structure is not damaged when the media access port is produced. For that reason such a media access port is always created either before or during the packaging of the MEMS element, which is relatively complex.

### SUMMARY OF THE INVENTION

According to the present invention, a structural concept for components of the type described here is provided, which may be implemented in a simple and cost-effective manner and which may be used to protect the micromechanical structure of MEMS elements very effectively against particles and interfering environmental influences despite media access.

According to the present invention, this is achieved in that the cap structure closes at least one first cavity section above the micromechanical component and at least one second cavity section on the side of this micromechanical component, that the two cavity sections are connected to one another, the connection area between the two cavity sections being configured as particle filters, and that the media connection port is situated in the area of the second cavity section.

Consequently, the media connection port is located on the side next to the micromechanical structure of the MEMS element. Based on this positioning, the media connection port may be produced later, i.e., after the cap structure is applied, without the risk of damaging the micromechanical structure of the MEMS element. The filter-like configuration of the connection area between the first cavity section including the micromechanical component and the second cavity section including the media access port prevents particles from penetrating the micromechanical structure and impairing its function during separation of the components and/or at the point of use of the component.

In principle, there are different possibilities for implementing the component concept according to the present invention, which concerns in particular the implementation of the cap structure including the two cavity sections and the filter structure. Here, the type of the MEMS element and, if necessary, the additional elements of the component must always be considered, as well as the requirements which the component must satisfy in the context of the 2nd level assembly on an application circuit board.

As already mentioned, the component concept according to the present invention is suitable in particular for MEMS pressure sensor elements and MEMS microphone elements. The positioning of the connection port on the side of the diaphragm has in these cases no effects on the signal detection, since the measuring pressure spreads uniformly across the connection area in both cavity sections. In principle, the component concept according to the present invention may, however, also be used for packaging other MEMS elements which require a media connection, for example, humidity sensors or gas sensors.

The cap structure for the MEMS element may be implemented either in the layered structure of the MEMS element or in the form of a structured cap wafer, which is mounted pressure-tight on the MEMS element.

In the first case, only one wafer must be processed. The micromechanical component is created in a functional layer of the layered structure on the MEMS substrate and, if necessary, partially exposed. Additional layers for the cap structure are subsequently deposited and structured above it. The cavity sections between the functional level and the cap structure are produced using sacrificial layer technology, parts of the micromechanical component also being exposed, if necessary.

In the second case, the MEMS element and the cap wafer are initially produced independently of one another. The two cavity sections and also the connection area including the filter structure may be created here in a relatively simple manner by appropriate structuring of the cap wafer. However, this variant requires an additional assembly step in which a pressure-tight connection is established between the MEMS element and the cap wafer.

In both cases, the cap structure is advantageously made from a material, whose thermal expansion coefficient is adapted to the thermal expansion coefficient of the material of the micromechanical component. This avoids thermally caused stresses in the component structure, which are able to severely impair the micromechanical function.

According to the present invention, the connection area between the two cavity sections is configured as a particle filter. In one advantageous specific embodiment of the present invention, the two cavity sections are connected to one another via one or multiple very fine channels. This effectively prevents particles from penetrating the micromechanical structure in the area of the first cavity section. However, a certain filter effect may also be achieved by varying the cavity height. Thus, in another specific embodiment, the distance between the cap structure and the micromechanical functional layer of the MEMS element in the area of the first cavity section above the micromechanical component is significantly smaller than in the area of the second cavity section, in which the media connection port is located.

A relatively large cavity height in the area of the second cavity section also proves to be advantageous when the cap structure is opened later using a laser drilling method. This namely makes it possible to limit the depth drilling in a simple manner. For this purpose, the micromechanical functional layer may also be provided with a plating in the area under the bore as a stop layer for the laser drilling method.

The component concept according to the present invention includes both a bare die structure as well as the possibility of embedding the MEMS element and the cap structure at least partially in a molding compound. Additional elements may then also be accommodated in such a mold housing in a simple manner. In this case, it proves to be advantageous to initially provide the MEMS element with a completely closed cap structure, and then mount this structure, if necessary, on a component support together with other elements of the component. This system is then encapsulated using a molding compound. In this process, it is unnecessary to take any special measures for protecting the micromechanical structure, since it is already protected by the cap structure and does not come into contact with the molding compound. The media connection port is produced only after the molding process, which may be done using a laser drilling method. Here, the molding compound is first drilled open, and then the cap structure.

In conclusion, it may still be pointed out that the MEMS element may also include additional micromechanical components, for example, rotation rate sensor and/or acceleration sensor components. Advantageously, cavities with or without a media access port are then formed in the cap structure for these additional micromechanical components.

As has already been discussed above, there are various options for developing and refining the present invention in an advantageous manner. For this purpose, reference is made, on the one hand, to the further descriptions herein, including the dependent claims, on the other hand, to the following description of the exemplary embodiments of the present invention based on the drawings.

### BRIEF DESCRIPTION OF THE DRAWINGS

FIG. 1 shows a schematic sectional representation of a first component 100 according to the present invention including a MEMS pressure sensor element 10.

FIG. 2 shows a schematic sectional representation of a second component 200 according to the present invention including a MEMS sensor element 210.

### DETAILED DESCRIPTION

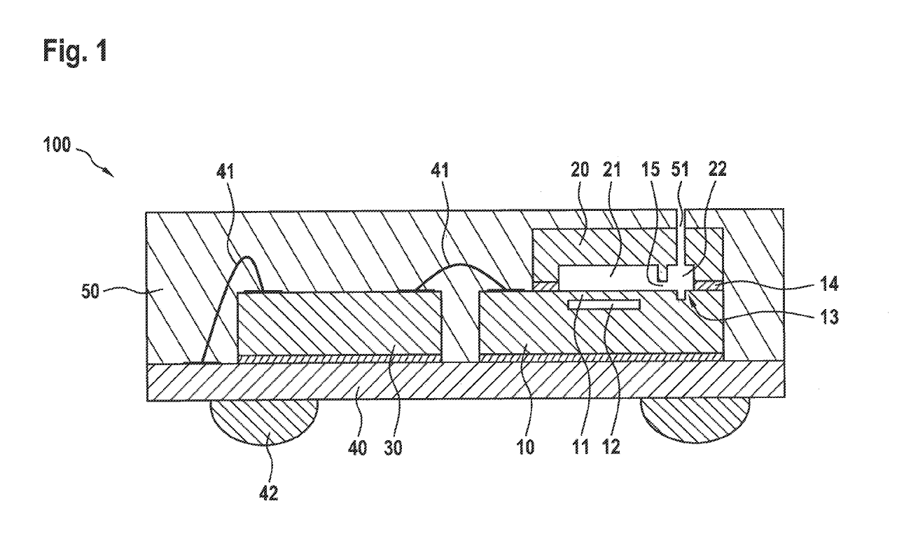

Component 100 shown in FIG. 1 includes a MEMS element 10 and an ASIC element 30, the functions of which complement one another. MEMS element 10 is a pressure sensor element 10 including a sensor diaphragm 11 for pressure detection. The measuring signals are forwarded to ASIC element 30 for processing and evaluation.

Sensor diaphragm 11 is formed as a layered structure of pressure sensor element 10 and spans a cavity 12. It is protected by a cap wafer 20, which is mounted above sensor diaphragm 11 on pressure sensor element 10. Sensor element 10 and cap wafer 20 are made from the same semiconductor material, for example, from silicon, or at least from materials having a similar thermal expansion coefficient, in order to avoid thermally caused stresses in the sensor area.

Cap wafer 20 was produced independently of pressure sensor element 10. Here, the assembly side of cap wafer 20 facing pressure sensor element 10 was structured to produce a first recess 21 and a second recess 22. First recess 21 extends across total diaphragm area 11 of pressure sensor element 10, while second recess 22 is situated clearly next to diaphragm area 11 in a chip area 13, where neither a micromechanical nor a circuit function is formed. Cap wafer 20 was connected here to pressure sensor element 10 via a structured bonding layer 14 in a pressure-tight manner. In the process, the two cavities or cavity sections 21 and 22 were produced between the structured surface of cap wafer 20 and the surface of pressure sensor element 10. Since bonding frame 14 encloses first recess 21 together with second recess 22, but does not separate them from one another, a pressure connection 15 exists between the two cavity sections 21 and 22. For the assembly of cap wafer 20 on pressure sensor element 10, for example, a seal glass process or also a eutectic bonding method based on Al—Ge may be used.

After the assembly of cap wafer 20, a defined internal pressure prevails in both cavity sections, namely the ambient pressure prevailing during the bonding process. Optionally, it is now possible to carry out initial pressure measurements at different temperatures in order to calibrate the pressure sensor.

In the exemplary embodiment shown here, ASIC element 30 and MEMS element 10 including still closed cap wafer 20 were mounted on a component support 40 and then encapsulated in a molding compound 50. Only after that was a connection port 51 created for applying pressure to sensor diaphragm 11. For this purpose, mold housing 50 and cap wafer 20 were drilled open using a laser drilling method, specifically in the area of second cavity section 22 on the side of sensor diaphragm 11. Here, the surface of pressure sensor element 10 was attacked in functionless chip area 13, since this surface area 13 was not protected. Pressure connection 15 between cavity section 22 and cavity section 21 above sensor diaphragm 11 acts as a particle filter here, since the opening cross section of this pressure connection 15 is very small.

Pressure sensor element 10 and ASIC element 30 are electrically connected to one another and to component support 40 via wire bonds 41. The assembly and electrical contacting of component 100 are carried out via component support 40 or via solder bumps 42 on the underside of component support 40.

For the determination of sensor sensitivity and for adjustment, the measurements using the defined internal pressure may now be compared with measurements made using a defined external pressure.

In an advantageous embodiment variant, the pressure sensor element may also include two largely identical sensor diaphragms, both of which are capped. If a pressure access is produced to only one of the two sensor diaphragms, the other sensor diaphragm may be used for reference pressure measurements, which then make it possible to determine drift due to external influences, such as stress and temperature fluctuations.

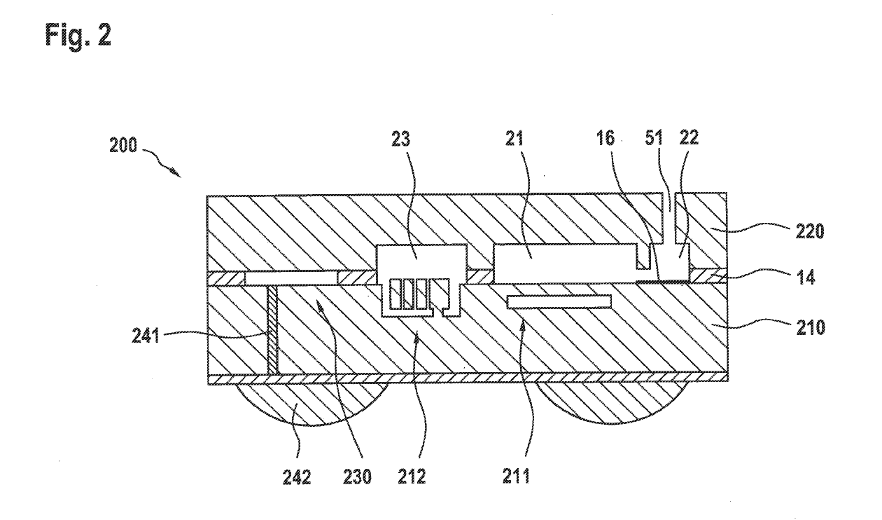

A mold housing was omitted in the case of component 200 shown in FIG. 2. Component 200 is implemented in the form of a chip stack which includes only one MEMS element 210 and one cap wafer 220. An ASIC component 230 and the micromechanical sensor structures of a pressure sensor 211 and an acceleration sensor 212 are implemented next to one another in the layer stack of MEMS element 210. Cap wafer 220 extends across the entire chip surface of MEMS element 210 and is connected to it in a pressure-tight manner.

In the assembly side of cap wafer 220 facing MEMS element 210, three recesses 21, 22, 23 are formed. First recess 21 extends across the entire diaphragm area of pressure sensor component 211, while second recess 22 is clearly situated next to this diaphragm area, in a chip area where neither a micromechanical nor a circuit function is formed. Third recess 23 extends across the entire area of the acceleration sensor component. Connection layer 14 between MEMS element 210 and cap wafer 220 is structured in such a way that cavity 23 is closed in a pressure-tight manner in the area of acceleration sensor component 212, and cavity 21 above the pressure sensor diaphragm is connected to cavity 22 on the side of the pressure sensor diaphragm, since bonding frame 14 is interrupted between these two cavities 21 and 22.

In a laser drilling method, a connection port 51 was produced in cap wafer 220 in the area of cavity 22, via which pressure is applied to the pressure sensor diaphragm. In order to protect the underlying surface of the MEMS element against the drilling action, this surface area was provided with a plating 16.

ASIC component 230 and sensor components 211 and 212 of MEMS element 210 are interconnected internally in the chip, which is not shown here in detail. The external electrical contacting of component 200 is carried out using vias 241 and solder bumps 242 on the rear side of MEMS element 210, which are also used for component assembly.

What is claimed is:

1. A component, comprising:
a MEMS element, in whose layered structure at least one micromechanical component is implemented, a function of which requires a media connection to the surroundings; and
a cap structure for the micromechanical component, the cap structure closing at least one first cavity section above the micromechanical component and at least one second cavity section on the side of the micromechanical component, so that the two cavity sections are connected to one another, the connection area between the two cavity sections being configured as particle filters;
wherein the MEMS element and the cap structure are at least partially embedded in a molding compound, and at least one media access port is drilled through the molding compound and the cap structure in the area of the second cavity section.

2. The component of claim 1, wherein a pressure sensor component including a sensor diaphragm or a microphone component including a microphone diaphragm is implemented in the layered structure of the MEMS element, and pressure is applied to the diaphragm via the at least one port in the cap structure in the area of the second cavity section on the side of the diaphragm.

3. The component of claim 1, wherein the cap structure is implemented in the layered structure of the MEMS element.

4. The component of claim 1, wherein the cap structure is implemented as a structured cap wafer, which is mounted on the MEMS element in a pressure-tight manner.

5. The component of claim 1, wherein the cap structure is formed from a material whose thermal expansion coefficient is adapted to the thermal expansion coefficient of the material of the micromechanical component.

6. The component of claim 1, wherein the first cavity section and the second cavity section are connected via at least one channel, which functions as a particle filter due to its small opening cross section.

7. The component of claim 1, wherein the distance between the cap structure and the micromechanical functional layer of the MEMS element is larger in the area of the second cavity section than in the area of the first cavity section above the micromechanical component.

8. The component of claim 1, wherein at least one additional micromechanical component is implemented in the layered structure of the MEMS element, and an additional cavity for this additional micromechanical component is formed in the cap structure.

9. A method for manufacturing a component, the method comprising:
providing a MEMS element, in whose layered structure at least one micromechanical component is implemented, the function of which requires a media connection to the surroundings; and
providing a cap structure for the micromechanical component, the cap structure closing at least one first cavity section above the micromechanical component and at least one second cavity section on the side of this micromechanical component, so that the two cavity sections are connected to one another, the connection area between the two cavity sections being configured as particle filters;
wherein the MEMS element is initially provided with a completely closed cap structure, wherein the MEMS element is then mounted on a component support and at least partially encapsulated using a molding compound, and wherein the at least one media connection port is produced only after the molding process in that the molding compound and the cap structure are drilled open in the area of the second cavity section.

10. The method of claim 9, wherein the at least one media connection port in the molding compound and in the cap structure is produced using laser drilling, the functional layer being provided with a plating in the area under this media connection port as a stop layer for the laser drilling.
